(19) United States
(12) Patent Application Publication
(10) Pub. No.: US 2005/0087740 A1
(43) Pub. Date: Apr. 28, 2005

(54) Organic electroluminescent display device of top emission type

(75) Inventors: Shoichiro Matsumoto, Ogaki-shi (JP); Ryuji Nishikawa, Gifu-shi (JP)

Correspondence Address: Barry E. Bretschneider;Morrison & Foerster LLP, Suite 300, 1650 Tysons Boulevard, McLean, VA, 22102, US

(73) Assignee: Sanyo Electric Co., Ltd., Moriguchi-city (JP)

(21) Appl. No.: 10/941,075

(22) Filed: Sep. 15, 2004

(30) Foreign Application Priority Data
Sep. 24, 2003 (JP) 2003-330929

(51) Int. Cl. H01L 29/04

(52) U.S. Cl. 257/72

(57) ABSTRACT

In an organic EL display device, emissive regions are arrayed in various patterns without depending on array patterns of the TFT formation regions and so on. A plurality of TFT formation regions PTr of pixels P is formed in a stripe array on a display portion. Emissive regions R1 of the organic EL element 11A emitting red light, emissive regions G1 of the organic EL element 11A emitting green light, and emissive regions B1 of the organic EL element 11A emitting blue light are arrayed on these TFT formation regions PTr. The emissive regions R1, G1, and B1 are disposed in delta array over the adjacent TFT formation regions PTr.

### CROSS-REFERENCE OF THE INVENTION

This invention is based on Japanese Patent Application No. 2003-330929, the content of which is incorporated by reference in its entirety.

### BACKGROUND OF THE INVENTION

1. Field of the Invention

This invention relates to an organic electroluminescent display device, particularly to an organic electroluminescent display device where flexibility in array positions of emissive regions of organic electroluminescent elements is increased

2. Description of the Related Art

In recent years, organic electroluminescent (hereafter, referred to as EL) display devices using EL elements are receiving attention as a new display device substituted for a CRT or an LCD. Particularly, an organic EL display device having thin film transistors (hereafter, referred to as TFTS) as switching elements for driving the organic EL elements is being developed.

A bottom emission type and a top emission type have been known in the organic EL display device. Hereinafter, the organic EL display device of bottom emission type will be described with reference to drawings

FIG. 13 shows an equivalent circuit diagram of a pixel P on a display portion (not shown) of the organic EL display device of bottom emission type of conventional art. Although a plurality of the pixels P is arrayed in a matrix of rows and columns on the display portion, FIG. 13 shows one pixel P only.

A gate signal line L1 supplying a gate signal Gn for selecting the pixels P and a drain signal line L2 supplying a display signal Dm for each of the pixels P are crossing each other in the pixel P. An organic EL element 11B serving as a self-emissive element, a driving TFT 61B for supplying a current to the organic EL element 11B, and a pixel selecting TFT 71B for selecting the pixel P are disposed in the region the crossing of these signal lines.

A gate of the pixel selecting TFT 71B is connected with the gate signal line L1 and supplied with the gate signal Gn therefrom, and a drain 71Bd of the pixel selecting TFT 71B is connected with the drain signal line L2 and supplied with the display signal Dm therefrom. A source 71Bs of the pixel selecting TFT 71B is connected with a gate of the driving TFT 61B. A drain 61Bd of the driving TFT 61B is connected with a pixel electrode 12B serving as an anode of the organic EL element 11B. A cathode 14B of the organic EL element 11B is supplied with power supply voltage CV.

The gate of the driving TFT 61B is connected with a storage capacitor Cs. The storage capacitor Cs is provided to store the display signal Dm to be applied to the pixel P for a field period by storing electric charge corresponding to the display signal Dm. The pixel P described above is operated as follows.

When the gate signal Gn becomes high level for one horizontal period, the pixel selecting TFT 71B turns on. Then, the display signal Dm is applied from the drain signal line L2 to the gate of the driving TFT 61B through the pixel selecting TFT 71B. Conductance of the driving TFT 61B changes in accordance with the display signal Dm supplied to the gate thereof, and a drive current in accordance with the conductance is supplied to the organic EL element 11B through the driving TFT 61B, thereby lighting the organic EL element 11B. When the driving TFT 61B turns off in accordance with the display signal Dm supplied to the gate, a drive current does not flow in the driving TFT 61B, thereby turning off the light of the organic EL element 11B.

Next, a structure of the pixel P will be described with reference to a schematic cross-sectional view. FIG. 14 is a schematic cross-sectional view of the pixel P. FIG. 14 shows one of the plurality of the pixels P arrayed in a matrix on a display portion 10. The organic EL element 11B of the display pixel P is of bottom emission type, and light emitted from the organic EL element 11B, i.e., a display light, is emitted outside through the transparent glass substrate 40B. A configuration of these elements will be described hereafter.

An active layer 62B, a gate insulating film 63B, a gate electrode 64B are formed on the transparent glass substrate 40B. A channel 62Bc, a source 62Bs, and a drain 62Bd are provided in the active layer 62B, the source 62Bs and the drain 62Bd being disposed on both sides of the channel 62B, respectively.

An interlayer insulating film 65B is formed on the whole surfaces of the gate insulating film 63B and the gate electrode 64B. A contact hole C3 is provided in the interlayer insulating film 65B in a position corresponding to the source 62Bs, and a power supply line L3 is provided therein by filling the contact hole C3 with a metal such as Al. Furthermore, an insulating film 66B is provided on the whole surface. A contact hole C4 is provided in the insulting film 66B in a position corresponding to the drain 62Bd, and metal such as Al fills the contact hole C4 so that the drain 62Bd and the pixel electrode 12B serving as an anode of the organic EL element 11B are in contact with each other.

The organic EL element 11B is formed in each of the pixels P, being isolated as an island. The organic EL element 11B is formed by laminating the pixel electrode 12B, an emissive layer 13B, and a cathode 14B reflecting light emitted from the emissive layer 13B without transmission, in this order. The cathode 14B is supplied with power supply voltage CV (not shown). In this organic EL element 11B, holes injected from the pixel electrode 12B and electrons injected from the cathode 14B are recombined in the emissive layer 13B. The recombined holes and electrons activate organic molecules forming the emissive layer 13B to generate excitons. Then, light is emitted from the emissive layer 13B in a process of radiation of the excitons and released outside from the transparent glass substrate 40B through the pixel electrode 12B.

Next the arrangements of the driving transistors, the pixel selecting transistors and the pixel electrodes 12B, which correspond to the emissive layer 13B, are explained. First, two types of arrangements, a stripe array and a delta array, are defined. A stripe array is a configuration in which a row of individual components are placed next to the neighboring row so that the individual components in the upper row are placed right next to the corresponding individual components in the lower row so as to form columns of the components. This arrangement is represented by the stacking arrangement of the white rectangular portions (PTr) shown in FIG. 2. A delta array is a configuration in which a row of individual components are placed next to the neighboring row so that the individual components in the upper low shit, relative to the lower row, in the row direction so as to place them out of the column positions of the lower row. This arrangement is represented by the stacking arrangement of the white rectangular portions (PTr) shown in FIG. 3.

Next, a “TFT formation region” is defined as one division of the substrate on which a corresponding driving TFT 61B and a corresponding pixel selecting TFT 71B are formed. This TFT formation region could include more than one driving TFT and more than one pixel selecting TFT as long as they are directed to one pixel element corresponding to the division of the substrate. In addition, the TFT formation region could include a storage capacitor Cs. In the drawings, the TFT formation regions are indicted by “PTr.”

FIG. 15 is a plan view showing an array example of a pixel electrode where the plurality of the pixel P is disposed in a stripe array. The TFT formation regions PTr are formed in a stripe array on the display portion 10. In these TFT formation regions PTr, pixel electrodes R2 of the organic EL elements emitting red light (R), pixel electrodes G2 of the organic EL elements emitting green light (g), and pixel electrodes B2 of the organic EL elements emitting blue light (B) are placed in a stripe array. Each of the pixel electrodes R2, G2, and B2 is disposed within each of the TFT formation regions PTr. That is, these pixel electrodes R2, G2 and B2 are arrayed so that light from the emissive layer 13B is not blocked by elements or wiring of the driving TFT 61B and so on.

Relevant technologies are disclosed in Japanese Patent Application Publication No. 2002-175029, for example.

However, in the organic EL display device of bottom emission type where the described pixel electrodes R2, G2 and B2 determine the emissive regions, light from the emissive layer 13B is released through the transparent glass substrate 40B. Therefore, the pixel electrodes R2, G2 and B2 of the organic EL element 11B are arrayed so that this light is not blocked by the elements or wiring of the driving TFT 61B and so on. This causes limitation on the array patterns of the emissive regions.

Furthermore, in a case where the pixel electrodes R2, G2 and B2 are covered with an insulating film having openings and the openings determine the emissive regions, limitation occurs on the array patterns of the emissive regions with the same reason as above.

The invention is directed to an organic EL display device of top emission type where flexibility on array patterns of the emissive regions is improved and the emissive regions are arrayed in various patterns.

### SUMMARY OF THE INVENTION

In an organic EL display device of top emission type of the invention, a plurality of TFT formation regions of display pixels is disposed in a stripe array on a display portion, and emissive regions of organic EL elements are disposed in a delta array over the adjacent TFT formation regions.

In an organic EL display device of top emission type of the invention, a plurality of TFT formation regions of pixels is formed in a delta array on a display portion, and emissive regions of organic EL elements are disposed in a stripe array over the adjacent TFT formation regions.

In an organic EL display device of top emission type of the invention, a plurality of TFT formation regions of pixels is formed in a stripe array on a display portion, and emissive regions of organic EL elements are disposed in a stripe array over the adjacent TFT formation regions, being shifted in a first direction in alternate rows.

In an organic EL display device of top emission type of the invention, a plurality of TFT formation regions of pixels is disposed in a delta array on a display portion, and emissive regions of organic EL elements are disposed in a delta array over the adjacent TFT formation regions, being shifted in a first direction in alternate rows.

In an organic EL display device of top emission type of the invention, emissive regions of organic EL elements are arrayed, being turned by 90 degrees based on a side of first or second direction.

This invention can realize an organic EL display device where the emissive regions are arrayed in various patterns without depending on array patterns of the driving TFTs, the pixel selecting TFTs, and the storage capacitors. This enables application of a glass substrate formed with TFTs in same array patterns to various organic EL display devices.

Furthermore, two emissive regions are formed in a region having the driving TFT, the pixel selecting TFT, and the storage capacitor in each of the pixels P to provide redundancy in the emissive region. Therefore, even when one of the emissive regions is unusable, light emission can be continued.

Furthermore, a plurality of regions having the driving TFTs, the pixel selecting TFTs, and the storage capacitors for the pixels is collectively provided in a specific region on the display portion, so that an area of the emissive regions can increase.

Furthermore, the emissive regions respectively corresponding to each of the colors can be formed having an area of different from each other. Therefore, influence (variance in luminance or life cycle) caused by differences in characteristics between emissive materials (organic materials etc forming the emissive layer 13A) which differ among colors can be minimized by adjusting the areas of the emissive regions.

### BRIEF DESCRIPTION OF THE DRAWINGS

FIGS. 1A and 1B are cross-sectional views of a pixel of an organic EL display device of top emission type of embodiments of the invention.

FIG. 2 is a plan view showing a display portion of an organic EL display device of top emission type of a first embodiment of the invention.

FIG. 3 is a plan view showing a display portion of an organic EL display device of top emission type of a second embodiment of the invention.

FIG. 4 is a plan view showing a display portion of an organic EL display device of top emission type of a third embodiment of the invention.

FIG. 5 is a plan view showing a display portion of an organic EL display device of top emission type of a fourth embodiment of the invention.

FIG. 6 is a plan view showing a display portion of an organic EL display device of top emission type of a fifth embodiment of the invention.

FIG. 7 is a plan view showing a display portion of an organic EL display device of top emission type of a sixth embodiment of the invention.

FIG. 8 is a plan view showing a display portion of an organic EL display device of top emission type of a seventh embodiment of the invention.

FIG. 9 is a plan view showing a display portion of an organic EL display device of top emission type of an eighth embodiment of the invention.

FIG. 10 is a plan view showing a display portion of an organic EL display device of top emission type of a ninth embodiment of the invention.

FIG. 11 is a plan view showing a display portion of an organic EL display device of top emission type of a tenth embodiment of the invention.

FIG. 12 is a plan view showing a display portion of an organic EL display device of top emission type of an eleventh embodiment of the invention.

FIG. 13 is an equivalent circuit diagram of a pixel of an organic EL display device of the invention.

FIG. 14 is a schematic cross-sectional view of an organic EL display device of bottom emission type of a conventional art.

FIG. 15 is a plan view showing a display portion (in a stripe array) of an organic EL display device of bottom emission type of the conventional art.

### DETAILED DESCRIPTION OF THE INVENTION

A structure of an organic EL display device of top emission type of embodiments of the invention will be described with reference to drawings.

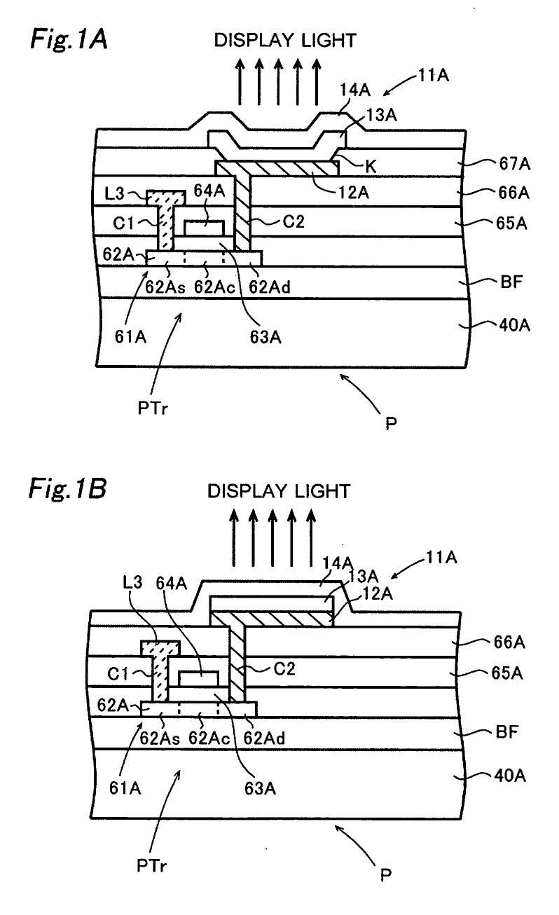

FIGS. 1A and 1B are cross-sectional views of a pixel P of the EL display device of top emission type of the embodiments of the invention. FIG. 1 shows one of a plurality of the pixels P arrayed in a matrix of rows and columns on a display portion (not shown). Note that an equivalent circuit diagram of the pixel P and its operation are the same as those shown in the description of the related art (FIG. 13). Furthermore, FIG. 1 shows only a periphery of the driving TFT 61A in a region PTr where the driving TFT 61A, the pixel selecting TFT 71A, and the storage capacitor Cs, which form the pixel P.

In this embodiment, an organic EL element 11A of the pixel P is an organic EL element of top emission type where light generated from the organic EL element 11A, that is, a display light, is emitted outside through a transparent cathode 14A of the organic EL element 11A formed on the glass substrate 40A and not through the glass substrate 40A. A configuration of these elements will be described hereafter.

FIG. 1A is a cross-sectional view of the organic EL display device of top emission type of this embodiment in a case where a two-layered planarization insulating film is formed.

As shown in FIG. 1A, a buffer layer BF is formed on a glass substrate 40A. On the buffer layer BF, an active layer 62A formed by poly-crystallizing an a-Si film by laser irradiation, a gate insulating film 63A, and a gate electrode 64A formed of a metal having a high melting point such as Cr (chromium) or Mo (molybdenum) are formed in this order. The active layer 62A is provided with a channel 62Ac, a source 62As and a drain 62Ad, the source 62As and the drain 62Ad being disposed on both sides of the channel 62Ac, respectively.

An interlayer insulating film 65A formed by laminating an SiO₂ film, an SiNₓ film and an SiO₂ film in this order are formed on the whole surfaces of the gate insulating film 63A and the gate electrode 64A. A contact hole C1 is provided in the interlayer insulating film 65A in a position corresponding to the source 62As, and a power supply line L3 to be supplied with a positive power supply voltage PVdd is provided by filling the contact hole C1 with a metal such as Al. Furthermore, a first planarization insulating film 66A for planarizing a surface, which is made of, for example, an organic resin, is formed on the whole surface. A contact hole C2 is provided in the first planarization insulating film 66A in a position corresponding to the drain 62Ad, and metal such as Al fills the contact hole C2 so that the drain 62Ad and the pixel electrode 12A serving as an anode of the organic EL element 11A are in contact with each other. The pixel electrode 12A is an electrode made of Al and so on, which reflects light without transmission. The pixel electrode 12A can be transparent or half-transparent.

On the first planarization insulating film 66A or on part of the first planarization insulating film 66A and the pixel electrode 12A, a second planarization insulating film 67A (e.g. made of an organic resin) having an opening K is formed. An emissive layer 13A is formed on the pixel electrode 12A in a position corresponding to the opening K, and a transparent cathode 14A transmitting light emitted from the emissive layer 13A is formed thereon. The transparent cathode 14A is supplied with power supply voltage CV (not shown). Light emitted from the emissive layer 13A is emitted through the transparent cathode 14A and not through the pixel electrode 12A. A half-transparent cathode can be used instead of the transparent cathode 14A.

In this embodiment, when the described two-layered planarization insulating film is formed, the size of the emissive region (planar region releasing light emitted from the emissive layer 13A outside) depends on the opening K of the second planarization insulating film 67A.

Although the organic EL display device of top emission type described above has the two-layered planarization insulating film (the first and second planarization insulating films 66A and 67A), the organic EL display device of top emission type can be formed with a single layer of a planarization insulating film. Next, an embodiment in which a single layer of the planarization insulating film is formed will be described with reference to drawings.

FIG. 1B is a cross-sectional view of the organic EL display device of top emission type of this embodiment in which a single layer of the planarization insulating film is formed. Note that the same numerals are provided to the same components as those of FIG. 1A, and description thereof will be omitted in FIG. 1B.

As shown in FIG. 1B, the organic EL element 11A is formed in each of the pixels P, being isolated as an island. The organic EL element 11A is formed by laminating the pixel electrode 12A, the emissive layer 13A, and the transparent cathode 14A transmitting light emitted from the emissive layer 13A, in this order. The transparent cathode 14A is supplied with power supply voltage CV (not shown). Light emitted from the emissive layer 13A is released out through the transparent cathode 14A without transmitting through the pixel electrode 12A. A half-transparent cathode can be used instead of the transparent cathode 14A.

In this embodiment, since the single layer of the planarization insulating film is formed, the size of the emissive region depends on the contact area between the pixel electrode 12A and the emissive layer 13A (the size of the overlapping area of the pixel electrode 12A and the emissive layer 13A).

In each of the embodiments shown in FIGS. 1A and 1B, it is preferable that the pixel electrode 12A and corresponding TFT formation region PTr overlap each other at least in a region for contact. The contact holes respectively provided in each of the TFT formation regions PTr can be disposed in different regions in the TFT formation regions PTr.

When the organic EL display device of these embodiments is of full color display type, three pixels each emitting red light (R), green light (G) and blue light (B) form one color pixel (not shown) to provide full color display based on the principle of three primary colors of light. Although there are several methods of emitting the three colors, a three-color-light emitting method is used in this embodiment. That is, each of the emissive layers 13A in the pixels, which corresponds to each of the three colors, is made of an organic material corresponding to each of the colors.

Since the pixel P has the structure described above, the emissive regions, the size of which depends on the opening K of the second planarization insulating film 67A or the overlapping region of the pixel electrode 12A and the emissive layer 13A, can be arrayed without being limited by elements or wiring of the driving TFT 61A and so on formed on the glass substrate 40A. This increases flexibility in array patterns of the emissive regions or the TFT formation regions PTr, and the emissive region can be formed in various array patterns when seen from above a front surface of the display portion.

Next, embodiments where the emissive regions are arrayed in various patterns on the TFT formation regions PTr will be described with reference to drawings. Note that description will be made hereafter on the organic EL display device of top emission type performing full color display. That is, three emissive regions of the pixels each emitting red light (R), green light (G) and blue light (B) operates as one unit, and a plurality of the units is arrayed in positions adjacent to each other.

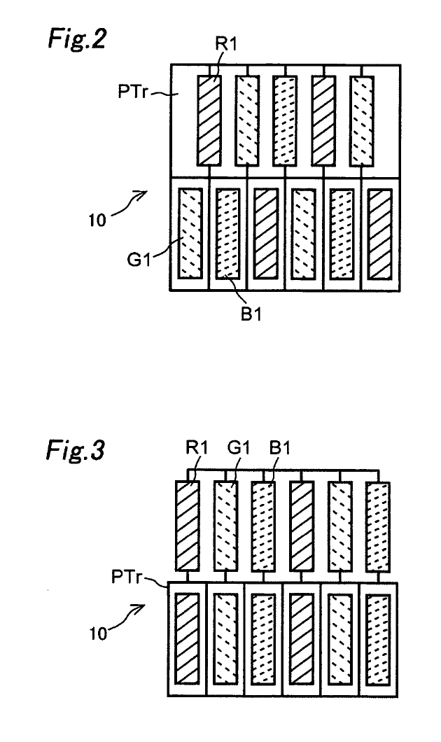

FIG. 2 is a plan view showing a display portion 10 of the organic EL display device of top emission type of a first embodiment of the invention. A plurality of TFT formation regions PTr of the pixels P, that is, a plurality of regions where the driving TFT 61A, the pixel selecting TFT 71A, and the storage capacitor Cs are formed, is formed in a rectangular shape and disposed in a stripe array on the display portion 10. Emissive regions R1, G1 and B1 of the organic EL element 11A respectively forming each of the pixels P are formed in a rectangular shape with same size, and placed in a delta array over the adjacent TFT formation regions PTr.

FIG. 3 is a plan view showing a display portion 10 of an organic EL display device of top emission type of a second embodiment. A plurality of TFT formation regions PTr is formed in a rectangular shape and disposed in a delta array on the display portion 10. Emissive regions R1, G1, and B1 are respectively formed in a rectangular shape with the same size and disposed in a stripe array, lying over the adjacent TFT formation regions PTr in the alternate rows where the TFT formation regions PTr are shifted.

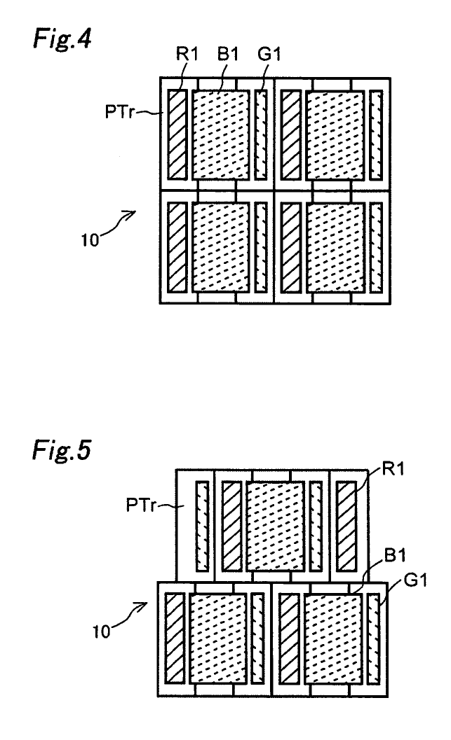

FIG. 4 is a plan view showing a display portion 10 of an organic EL display device of top emission type of a third embodiment. A plurality of TFT formation regions PTr is formed in a rectangular shape and disposed in a stripe array on the display portion 10. Emissive regions R1, G1 and B1 respectively form a rectangular shape having size different from each other, and are placed in a stripe array over the adjacent TFT formation regions PTr (for example, extending in a first (row) direction over the pixels P arrayed in a matrix).

FIG. 5 is a plan view showing a display portion 10 of an organic EL display device of top emission type of a fourth embodiment. A plurality of TFT formation regions PTr forms a rectangular shape and placed in a delta array on the display portion 10, being shifted in a row direction in alternate rows. Emissive regions R1, G1 and B1 respectively form a rectangular shape having different sizes, and are placed in a delta array over the adjacent TFT formation regions PTr (for example, extending in a first (row) direction over the pixels P arrayed in a matrix).

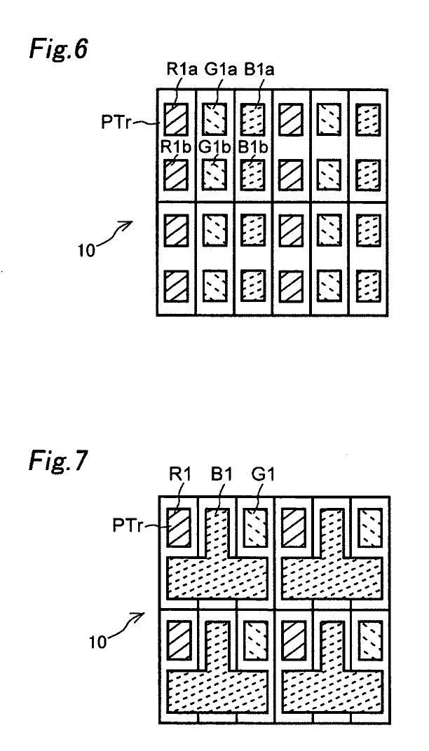

FIG. 6 is a plan view showing a display portion 10 of an organic EL display device of top emission type of a fifth embodiment. A plurality of TFT formation regions PTr is formed in a rectangular shape and placed in a stripe array on the display portion 10. In each of the TFT formation regions PTr, a plurality (e.g. two) of emissive regions i.e. emissive regions R1a and R1b, G1a and G1b, and B1a and B1b is respectively formed and disposed in a stripe array, providing redundancy in the emissive regions. For example, the two emissive regions R1a and R1b are formed being isolated as an island, and commonly connected with the driving TFT 61A (not shown). This can secure emission of corresponding color light even when any one of the emissive regions becomes unusable.

FIG. 7 is a plan view showing a display portion 10 of an organic EL display device of top emission type of a sixth embodiment. A plurality of TFT formation regions PTr forms a rectangular shape and placed in a stripe array on the display portion 10. Some of emissive regions R1, G1, and B1 respectively form a shape different from others and are disposed in a stripe array over the adjacent TFT formation regions PTr.

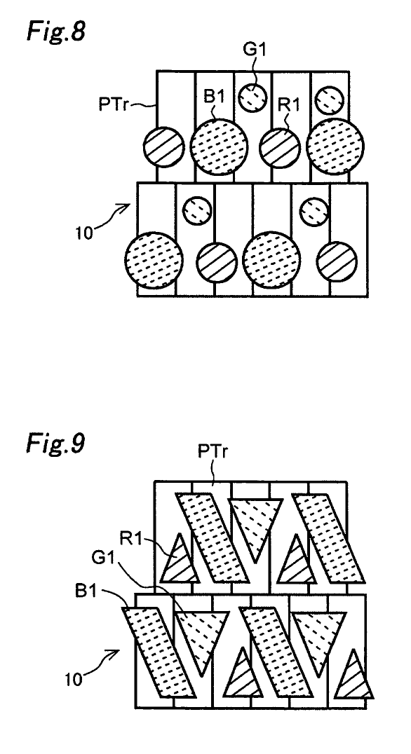

FIG. 8 is a plan view showing a display portion 10 of an organic EL display device of top emission type of a seventh embodiment. A plurality of TFT formation regions PTr forms a rectangular shape and placed in a delta array on the display portion 10. Emissive regions R1, G1, and B1 form a shape (e.g. circle) other than a rectangular shape and are placed in a delta array over the adjacent TFT formation regions PTr.

FIG. 9 is a plan view showing a display portion 10 of an organic EL display device of top emission type of an eighth embodiment. A plurality of TFT formation regions PTr forms a rectangular shape and disposed in a delta array on the display portion 10. Emissive regions R1, G1, and B1 respectively form various shapes other than rectangular shapes and are disposed in a delta array over the adjacent TFT formation regions PTr.

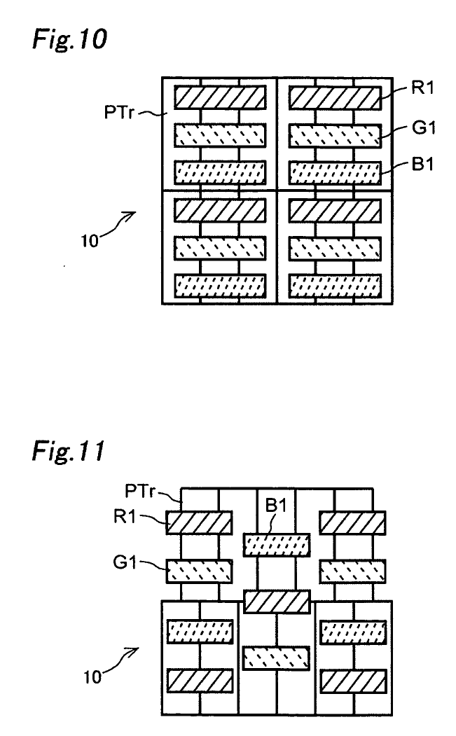

FIG. 10 is a plan view showing a display portion 10 of an organic EL display device of top emission type of a ninth embodiment. A plurality of TFT formation regions PTr forms a rectangular shape and placed in a stripe array on the display portion 10. Emissive regions R1, G1 and B1 respectively form a rectangular shape and are disposed in a stripe array over the adjacent TFT formation regions PTr, being turned by 90 degrees based on sides of first (row) or second (column) direction of the pixels P arrayed in a matrix.

FIG. 11 is a plan view showing a display portion 10 of an organic EL display device of top emission type of a tenth embodiment. A plurality of TFT formation regions PTr forms a rectangular shape and is disposed in a delta array on the display portion 10. Emissive regions R1, G1 and B1 respectively form a rectangular shape and are disposed in a delta array over the adjacent TFT formation regions PTr, being turned by 90 degrees based on sides of first (row) or second (column) direction of the pixels P arrayed in a matrix.

With the array patterns shown in FIGS. 10 and 11, only the array directions of the emissive regions R1, G1, and B1 may be changed, for example, for a display panel which is vertically long and a display panel which is horizontally long, by changing the array patterns of the driving TFT 61A and the pixel selecting TFT 71A. This provides an advantage of minimizing design alternation.

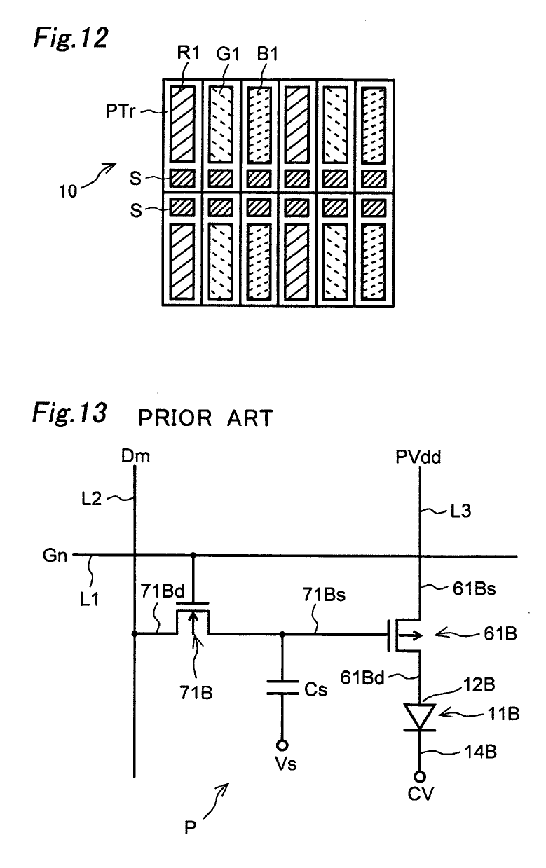

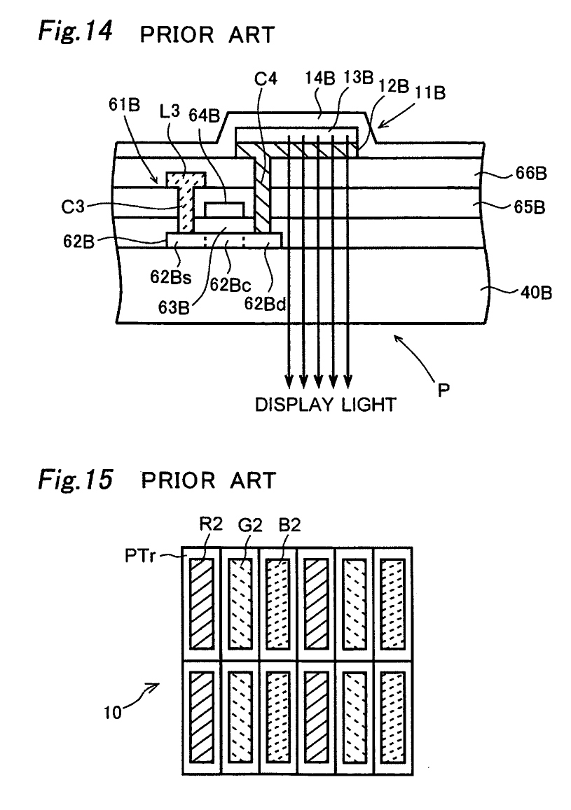

FIG. 12 is a plan view showing a display portion 10 of an organic EL display device of top emission type of an eleventh embodiment. Emissive regions R1, G1 and B1 are disposed in a stripe array on the display portion 10. The driving TFTs and the pixel selecting TFTs in TFT formation regions PTr respectively corresponding to each of a plurality of the emissive regions R1, G1, and B1 are collectively placed in specific regions S to make room for the organic EL 11A formation regions in the TFT formation regions PTr on the display portion 10. This can increase an area of the emissive regions.

As described above, the emissive regions R1, G1 and B1 of the organic EL element 11A can be freely arrayed without limitation of the TFT formation regions PTr on the display pixel P, so that various array patterns of the emissive regions can be realized. Various array patterns of the emissive regions are possible on the glass substrates 40A arrayed with respect to the TFT formation regions PTr.

Furthermore, the two emissive regions R1a and R1b, G1a and G1b, and B1a and B1b may be separately formed in each of the TFT formation regions PTr, thereby providing redundancy in the emissive regions. Therefore, even if one of the two emissive regions becomes unusable, light emission of corresponding color light can be secured.

Furthermore, the driving TFTs and the pixel selecting TFTs in the TFT formation regions PTr are collectively provided in the specific regions S on the display portion 10 so that the area of the emissive regions can increase.

Furthermore, in the third to fourth embodiments and the sixth to eighth embodiments, the emissive regions. R1, G1, and B1 respectively corresponding to each of the colors are formed having different areas. This enables minimization of influence (variance in luminance or life cycle) caused by differences in characteristics (light emission efficiency, life cycle, etc) between emissive materials (organic material forming the emissive layers 13A, etc) of different colors by adjusting the areas of the emissive regions R1, G1 and B1.

1. An organic electroluminescent display device of top emission type, comprising:
a substrate;
a plurality of organic electroluminescent elements disposed on the substrate;
a plurality of driving transistors driving the organic electroluminescent elements and disposed on the substrate;
a plurality of pixel selecting transistors selecting the organic electroluminescent elements and disposed on the substrate;
a plurality of divisions of the substrate each having a driving transistor and a pixel selecting transistor formed thereon, the divisions being arranged in a stripe array; and
a plurality of emissive regions of the organic electroluminescent elements arranged in a delta array.

2. The organic electroluminescent display device of top emission type of claim 1, wherein the emissive regions have a same size.

3. The organic electroluminescent display device of top emission type of claim 1, wherein the emissive regions corresponding to one color have a size different from the emissive regions corresponding to other colors.

4. The organic electroluminescent display device of top emission type of claim 1, wherein a longitudinal direction of the emissive regions is approximately normal to a longitudinal direction of the divisions.

5. The organic electroluminescent display device of top emission type of claim 1, wherein at least two emissive regions are formed in some of the divisions

6. The organic electroluminescent display device of top emission type of claim 1, wherein the emissive region occupies part of a corresponding division that is not occupied by corresponding driving and pixel selecting transistors at least in some of the divisions.

7. An organic electroluminescent display device of top emission type, comprising:
a substrate;
a plurality of organic electroluminescent elements disposed on the substrate;
a plurality of driving transistors driving the organic electroluminescent elements and disposed on the substrate;
a plurality of pixel selecting transistors selecting the organic electroluminescent elements and disposed on the substrate;
a plurality of divisions of the substrate each having a driving transistor and a pixel selecting transistor formed thereon, the divisions being arranged in a delta array; and
a plurality of emissive regions of the organic electroluminescent elements arranged in a stripe array.

8. The organic electroluminescent display device of top emission type of claim 7, wherein the emissive regions have a same size.

9. The organic electroluminescent display device of top emission type of claim 7, wherein the emissive regions corresponding to one color have a size different from the emissive regions corresponding to other colors.

10. The organic electroluminescent display device of top emission type of claim 7, wherein a longitudinal direction of the emissive regions is approximately normal to a longitudinal direction of the divisions.

11. The organic electroluminescent display device of top emission type of claim 7, wherein at least two emissive regions are formed in some of the divisions

12. The organic electroluminescent display device of top emission type of claim 7, wherein the emissive region occupies part of a corresponding division that is not occupied by corresponding driving and pixel selecting transistors at least in some of the divisions.

13. An organic electroluminescent display device of top emission type, comprising:
a substrate;
a plurality of organic electroluminescent elements disposed on the substrate;
a plurality of driving transistors driving the organic electroluminescent elements and disposed on the substrate;
a plurality of pixel selecting transistors selecting the organic electroluminescent elements and disposed on the substrate;
a plurality of divisions of the substrate each having a driving transistor and a pixel selecting transistor formed thereon, the divisions being arranged in a stripe array; and
a plurality of emissive regions of the organic electroluminescent elements arranged in a stripe array, wherein
one of the emissive regions extends through three consecutive divisions in a row.

14. The organic electroluminescent display device of top emission type of claim 13, wherein the emissive regions have a same size.

15. The organic electroluminescent display device of top emission type of claim 13, wherein the emissive regions corresponding to one color have a size different from the emissive regions corresponding to other colors.

16. The organic electroluminescent display device of top emission type of claim 13, wherein a longitudinal direction of the emissive regions is approximately normal to a longitudinal direction of the divisions.

17. The organic electroluminescent display device of top emission type of claim 13, wherein at least two emissive regions are formed in some of the divisions

18. The organic electroluminescent display device of top emission type of claim 13, wherein the emissive region occupies part of a corresponding division that is not occupied by corresponding driving and pixel selecting transistors at least in some of the divisions.

19. An organic electroluminescent display device of top emission type, comprising:
a substrate;
a plurality of organic electroluminescent elements disposed on the substrate;
a plurality of driving transistors driving the organic electroluminescent elements and disposed on the substrate;
a plurality of pixel selecting transistors selecting the organic electroluminescent elements and disposed on the substrate;
a plurality of divisions of the substrate each having a driving transistor and a pixel selecting transistor formed thereon, the divisions being arranged in a delta array; and
a plurality of emissive regions of the organic electroluminescent elements arranged in a delta array.

20. The organic electroluminescent display device of top emission type of claim 19, wherein the emissive regions have a same size.

21. The organic electroluminescent display device of top emission type of claim 19, wherein the emissive regions corresponding to one color have a size different from the emissive regions corresponding to other colors.

22. The organic electroluminescent display device of top emission type of claim 19, wherein a longitudinal direction of the emissive regions is approximately normal to a longitudinal direction of the divisions.

23. The organic electroluminescent display device of top emission type of claim 19, wherein at least two emissive regions are formed in some of the divisions

24. The organic electroluminescent display device of top emission type of claim 19, wherein the emissive region occupies part of a corresponding division that is not occupied by corresponding driving and pixel selecting transistors at least in some of the divisions.
